(19) United States
(12) Patent Application Publication
(10) Pub. No.: US 2025/0273535 A1
(43) Pub. Date: Aug. 28, 2025

(54) ELECTRONIC DEVICE DUAL SIDE MOLDED SOLDERMASKLESS PACKAGE SUBSTRATE PACKAGE FOR IMPROVED THERMAL DISSIPATION AND THERMOMECHANICAL INTEGRITY

(71) Applicant: Texas Instruments Incorporated, Dallas, TX (US)

(72) Inventors: Jaimal Williamson, McKinney, TX (US); Chun Ping Lo, Allen, TX (US); Blake Travis, Richardson, TX (US); Yutaka Suzuki, Allen, TX (US)

(21) Appl. No.: 18/589,297

(22) Filed: Feb. 27, 2024

(51) Int. Cl. H01L 23/373; H01L 21/48; H01L 21/56; H01L 23/31; H01L 23/498

(52) U.S. Cl. CPC H01L 23/3737; H01L 21/4853; H01L 21/565; H01L 23/3107; H01L 23/49816; H01L 23/49822

(57) ABSTRACT

An electronic device includes a multilevel package substrate having opposite first and second sides, a semiconductor die attached to the first side, a first molded package structure on the first side, and a second molded package structure on the second side and spaced apart from the first molded package structure. A method of fabricating an electronic device includes attaching a semiconductor die to a first side of a soldermaskless multilevel package substrate, forming a first molded package structure on the first side of the multilevel package substrate, and forming a second molded package structure on an opposite second side of the multilevel package substrate and spaced apart from the first molded package structure.

### BACKGROUND

Thermal performance is important to increase device power density and/or reduce electronic device and system size. For example, improving heat removal or thermal dissipation of flip chip, chip-scale package (FCCSP), flip chip ball grid array (FCBGA) and other electronic devices packages is a design goal for modern electronic device applications. Ajinomoto build-up film (ABF) dielectric material used as an insulator in FCBGA substrates is under supply constraints due to the proliferation of 5G wireless communications, artificial intelligence (AI), high performance computing (HPC) and other electronic device applications. Some applications call for larger body sizes (e.g., above 50 mm body) and higher substrate layer count for high IO counts, where ABF is a currently popular substrate material, and smaller FCBGA form factors (e.g., below 24 mm) are less attractive in terms of cost incentive to substrate suppliers. Transitioning select FCBGA packages currently using ABF to substrates made with prepreg dielectric materials can help lower cost, such as by expanding traditional smaller FCCSP (strip-based with prepreg) body sizes to accommodate larger body sizes, which have aligned traditionally to FCBGA (singulated units) form factors. Transitioning the smaller body size FCBGA (ABF-based) footprint to a non-traditional larger prepreg-dielectric based (e.g., FCCSP) footprint, however, presents assembly manufacturing yield and thermal performance challenges that are not present in current FCBGA technology. In particular, larger body FCCSP designs suffer from more warpage during manufacturing. In addition, conventional FCCSP solutions are not as thermally dissipative as FCBGAs.

### SUMMARY

In one aspect, an electronic device includes a multilevel package substrate having opposite first and second sides, a semiconductor die attached to the first side, a first molded package structure on the first side, and a second molded package structure on the second side and spaced apart from the first molded package structure.

In another aspect, a system includes a circuit board and an electronic device attached to the circuit board, where the electronic device includes a multilevel package substrate having opposite first and second sides and a terminal soldered to a conductive feature of the circuit board, a semiconductor die attached to the first side, a first molded package structure on the first side, and a second molded package structure on the second side and spaced apart from the first molded package structure.

In a further aspect, a method of fabricating an electronic device includes attaching a semiconductor die to a first side of a soldermaskless multilevel package substrate, forming a first molded package structure having a first thermal conductivity that is greater than 3 W/mK on the first side of the multilevel package substrate, and forming a second molded package structure having a second thermal conductivity that is greater than 3 W/mK on an opposite second side of the multilevel package substrate and spaced apart from the first molded package structure.

### BRIEF DESCRIPTION OF THE DRAWINGS

FIG. 1 is a partial sectional side elevation view taken along line 1-1 a of FIG. 1A of a system with an electronic device installed on a circuit board and having a multilevel package substrate with the top and bottom side molded package structures.

FIG. 1A a is a sectional bottom plan view of the electronic device taken along line 1-A-1A a of FIG. 1

FIG. 1B is a partial sectional side elevation view of a system with another example electronic device installed on a circuit board and having a multilevel package substrate with the top and bottom side molded package structures and an exposed top die surface.

FIG. 1C is a partial sectional side elevation view of a system with another example electronic device installed on a circuit board and having a multilevel package substrate with the top and bottom side molded package structures and a lid on a top die surface.

FIG. 2 is a flow diagram of a method of fabricating an electronic device.

FIGS. 3-13 are partial side elevation views of the electronic device of FIGS. 1 and 1A undergoing fabrication processing according to the method of FIG. 2.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. The example structures include layers or materials described as over or on another layer or material, which can be a layer or material directly on and contacting the other layer or material where other materials, such as impurities or artifacts or remnant materials from fabrication processing may be present between the layer or material and the other layer or material. Unless otherwise stated, “about,” “approximately,” or “substantially” preceding a value means +/−10 percent of the stated value. One or more structures, features, aspects, components, etc., may be referred to herein as first, second, third, etc., such as first and second terminals, first, second, and third, wells, etc., for ease of description in connection with a particular drawing, where such are not to be construed as limiting with respect to the claims. Various disclosed structures and methods of the present disclosure may be beneficially applied to an electronic device, manufacturing, and/or operating an electronic device such as an integrated circuit. While such examples may be expected to provide various improvements, no particular result is a requirement of the present disclosure unless explicitly recited in a particular claim.

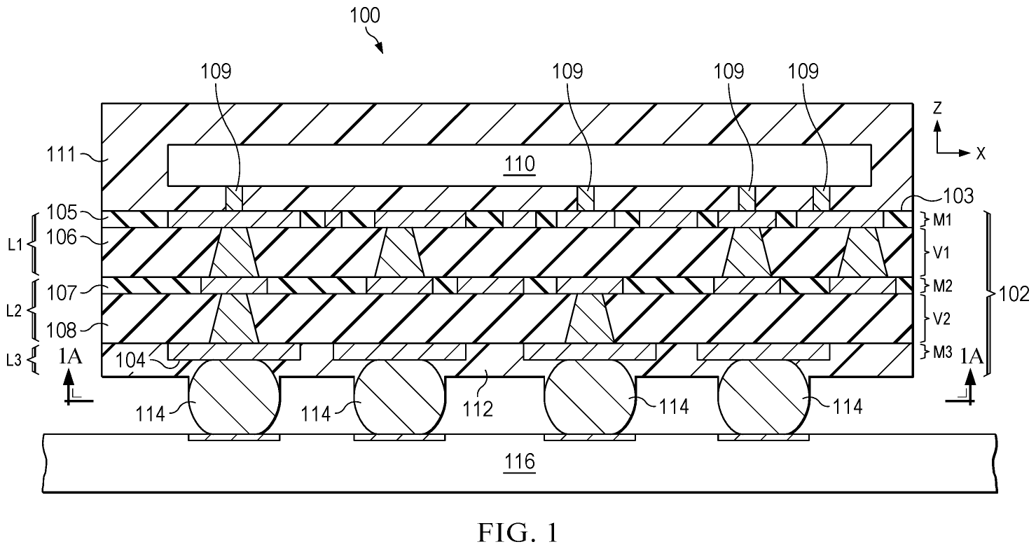

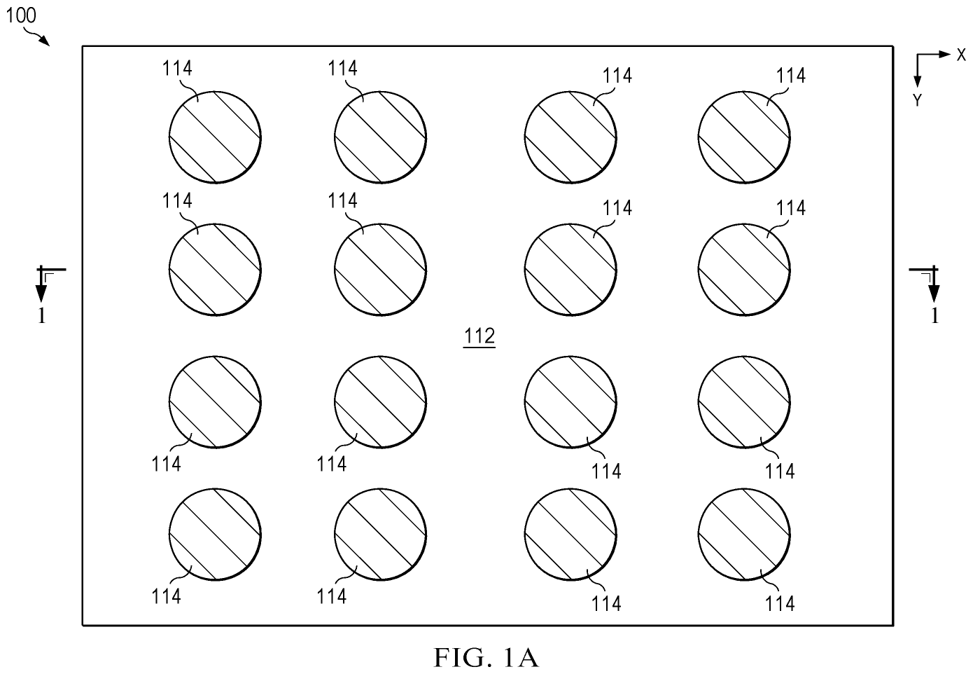

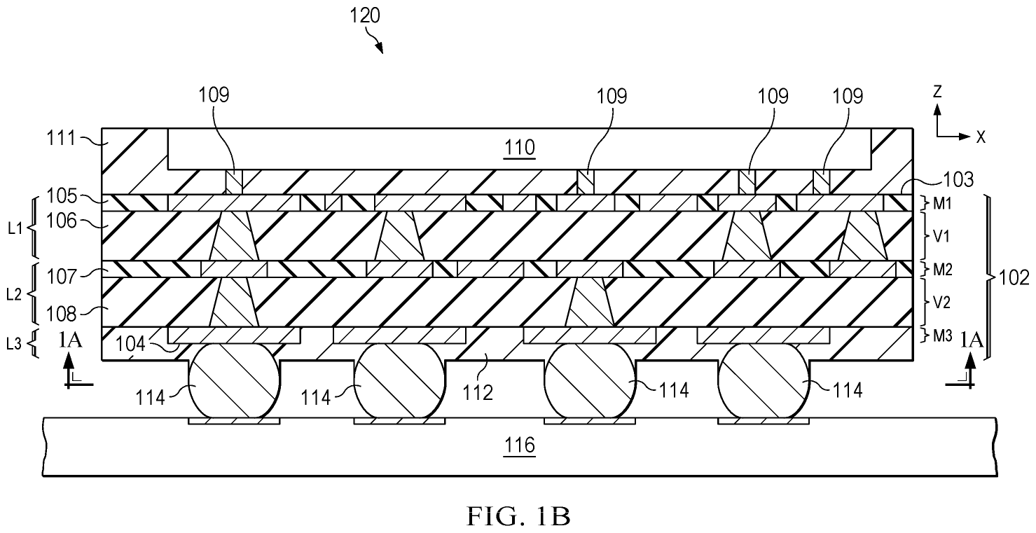

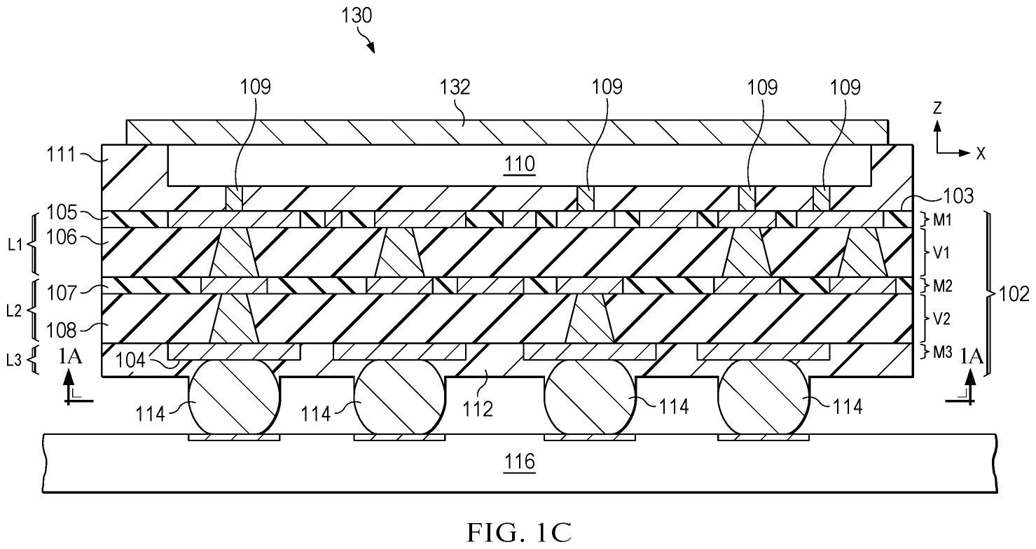

FIGS. 1 and 1A show an electronic device 100 having a soldermaskless multilevel package substrate 102 with a first (e.g., top) side 103 and an opposite second (e.g., bottom) side 104. The multilevel package substrate 102 includes no solder mask on either of the opposite sides 103 and 104. The multilevel package substrate 102 is a three level stacked structure that includes a top or first level L1 having dielectric layers 105 and 106 and patterned conductive metal features including first metal trace layer features M1 and first metal via layer features V1. A second level L2 includes dielectric layers 107 and 108, as well as second metal trace layer features M2, and second metal via layer features V2. A third level L3 in the illustrated example includes a third metal trace layer features M3. In other examples, any suitable number of two or more levels can be used with trace and/or via layer features. Conductive metal terminals 109 of a semiconductor die 110 are attached by solder connections to top sides of corresponding first metal trace layer features M1 to provide mechanical and electrical connection of the semiconductor die 110 to the multilevel package substrate 102. The example electronic device 100 is a flip chip chip-scale package (FCCSP) with solder connections between the terminals 109 and the multilevel package substrate 102. In other examples, different package forms and types can be used.

As best shown in FIG. 1, the electronic device 100 includes a dual side (e.g., top and bottom) molded configuration with first and second side molded package structures 111 and 112, respectively. The first molded package structure 111 extends at least partially on the top or first side 103, and the second molded package structure 112 extends at least partially on the bottom or second side 104 of the molded package substrate 102. The second molded package structure 112 is spaced apart from (e.g., separate from) the first molded package structure 111.

The electronic device 100 is shown attached to a circuit board 116 in a system, such as a communications, AI, HPC or other application. The dual side molded multilevel package substrate configuration has no solder mask on either of the sides 103 or 104, and this is referred to as a soldermaskless multilevel package substrate 102. The electronic device 100 in one example includes solder balls 114 that contact a conductive metal feature M3 on the second side 104 of the multilevel package substrate 102 and provide electrical and mechanical connection of the electronic device 100 to circuitry of the host circuit board 116.

The illustrated implementation provides a ball grid array (BGA) form with high I/O density interconnection advantages, as further shown in FIG. 1A. In other examples, different types and forms of electrical terminal connections and positioning can be used, for example, dual or quad flat no-lead or leadless (e.g., DFN, QFN) devices with conductive features of a bottom level of the multilevel package substrate 102 forming leads for soldering to a host circuit board, connective insertion into a socket (not shown), and/or different types of externally extending leads (e.g., gullwing leads, “j” type leads, etc.).

In certain examples, the molded package structures 111 and 112 can be or include any suitable molding compound or mold compound material, such as epoxy-based mold compound (e.g., EMC) having a thermal conductivity that is greater than that of solder mask materials to provide various benefits compared to conventional substrates with solder mask layers. For example, the dual molded substrate 102 in the electronic device 100 provides an advanced packaging solution to address multiple shortcomings of standard FCCSP technology including improved thermal performance in operation, substantially reduced substrate warpage during manufacturing, and reduced manufacturing cost.

Thermal performance can be addressed to an extent by over molded encapsulation of a semiconductor die with standard epoxy molding compound (EMC), but this approach is generally insufficient from a thermal conductivity standpoint and thermal performance improvement through substituting higher thermal conductivity EMC materials alone is limited and costly. Thicker semiconductor dies can be used for improved lateral heat spreading, but this involves a tradeoff with increased resistance due to longer path vs. increased interface area with thicker silicon and increased final device size which may be unacceptable for certain applications. Thermal performance may benefit from increased copper or other metal density in the substrate, but this may also increase device size as well as cost and complexity of the manufacturing process. Flip chip packages can be designed to include a copper or other metal lid to operate as a heat spreader to distribute heat, but this adds cost and complexity to the assembly process and may reduce process throughput.

The dual side molded structure of the electronic device 100 improves thermal performance during operation of the electronic device 100 in a host system by facilitating heat removal from the semiconductor die 110, particularly compared with solder mask-based substrate devices. In one implementation example of the electronic device 100, a 13 mm×13 mm three level FCCSP substrate having levels L1, L2, and L3 having implementations of the first and second molded package structures 111 and 112 was tested for thermal analysis of projected improvement in a simple lumped printed circuit board model and compared with simulated results for a similarly sized three level substrate having solder mask along the top and bottom sides. The solder mask- based substrate provided a simulated junction-to-ambient thermal resistance of approximately 25.8° C. per watt and a junction-two-board thermal resistance of approximately 5.1° C. per watt. Replacing the lower thermal conductivity solder mask with higher thermal conductivity EMC in the simulated example soldermaskless dual side molded multilevel package substrate 102 with the first and second molded package structures 111 and 112 provided a junction-to-ambient thermal resistance of approximately 25.4° C. per watt and a junction-two-board thermal resistance of approximately 4.7° C. per watt, representing 1.8% and 8.4% reductions in thermal resistance and corresponding percentage improvements in thermal conductivity.

In one example, the first molded package structure 111 provides heat dissipation from the semiconductor die 110 laterally and upward to the ambient environment, and the second molded package structure 112 helps dissipate heat downward toward the host circuit board 116 (e.g., along the Z direction in FIG. 1). In this regard, solder mask material generally has very low thermal conductivity such as 0.21 W/mK or less). In contrast, EMC material of the first and second molded package structures 111 and 112 have significantly higher thermal conductivity coefficients thank solder mask material, such as greater than 3 W/mK in certain examples. In these or another example, the thermal conductivity coefficients of the first and second molded package structures 111 and 112 are approximately 4.3 W/mK. The mold compound material of the first and second molded package structures 111 and 112 can be the same in one example. In another example, different mold compound materials are used for the first and second molded package structures 111 and 112, each having a thermal conductivity that is greater than 3 W/mK.

In the example of FIG. 1, moreover, the first molded package structure 111 encloses the

semiconductor die 110. FIGS. 1B and 1C show other example electronic devices 120 and 130, respectively, with similarly numbered structures and features as described above and in which the first molded package structure 111 extends along at least a portion of the first side 103 of the multilevel package structure 102 without enclosing the semiconductor die 110. In another implementation, first molded package structure 111 extends along at least a portion of the first side 103 of the multilevel package structure 102 and partially encloses the semiconductor die 110. The electronic device 120 in FIG. 1B has top and bottom side molded package structures 111 and 112, where a top surface of the semiconductor die 110 is exposed outside the first molded package structure 111. The electronic device 130 in FIG. 1C has a multilevel package substrate 102 with the top and bottom side molded package structures 111 and 112 and a lid 132 on a top surface of the semiconductor die 110. In other implementations, one or both of the example electronic device 120 and 130 of FIGS. 1B and 1C can optionally includes a further separate under molded structure (not shown), such as epoxy molding compound extending between a lower side of the semiconductor die 110 and a portion of the top side 103 of the multilevel package substrate 102, with another portion of the top side 103 of the multilevel package substrate 102 at least partially covered by the first molded package structure 111.

The second molded package structure 112 in certain examples encloses at least a portion of the third metal trace layer features M3 of the third level L3 of the multilevel package substrate 102 as shown in FIG. 1. The second molded package structure 112 extends on portions of the second level dielectric layer 108 laterally between conductive metal features M3 of the third level L3. In another implementation, the third level L3 includes a dielectric layer corresponding to the third metal trace layer features M3 and the second molded package structure 112 extends on portions of the third metal trace layer features M3 and the dielectric layer of the third level L3. In one implementation, moreover, the second molded package structure 112 contacts an upper portion of the respective solder balls 114. The first and second molded package structures 111 and 112 in the illustrated example extend to the lateral edges of the respective sides, although not a strict requirement of all possible implementations.

Described examples also advantageously reduce substrate manufacturing cost and complexity by eliminating materials and process steps from the manufacture of the multilevel package substrate 102. Constructing conventional substrates with solder mask material layers on the top and bottom sides requires solder resist masking, processing steps, and the cost of the solder mask material and extra time. These costs and steps can be mitigated or avoided during production of the various implementations of the example soldermaskless multilevel package substrate 102. The first and second molded package structures 111 and 112 are then created during packaging processing, for example, using molding equipment and materials to create molded package structures after semiconductor dies 110 have been attached to the soldermaskless substrate panel array (e.g., by flip chip die attachment and solder reflow operations).

The soldermaskless multilevel package substrate 102 also provides process yield advantage by mitigating substrate panel warpage during manufacturing. One example thermal-mechanically modeled implementation of the dual side molded soldermaskless multilevel package substrate 102 reduced warpage by approximately up to 85% from room temperature to reflow temperature. Reducing substrate warpage during manufacturing, particularly for soldermaskless multilevel package substrate panel array structures having rows and columns of concurrently processed substrate unit areas advantageously increases process yield and reduces scrap, thereby reducing manufacturing cost for various implementations of the electronic device 100 compared with using substrates having solder mask layers.

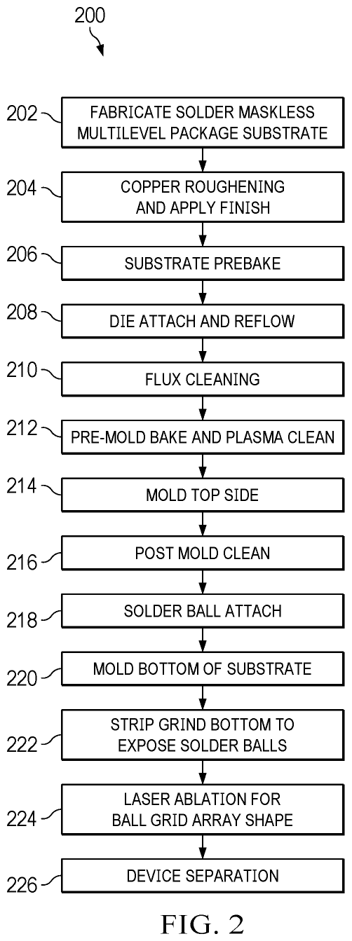

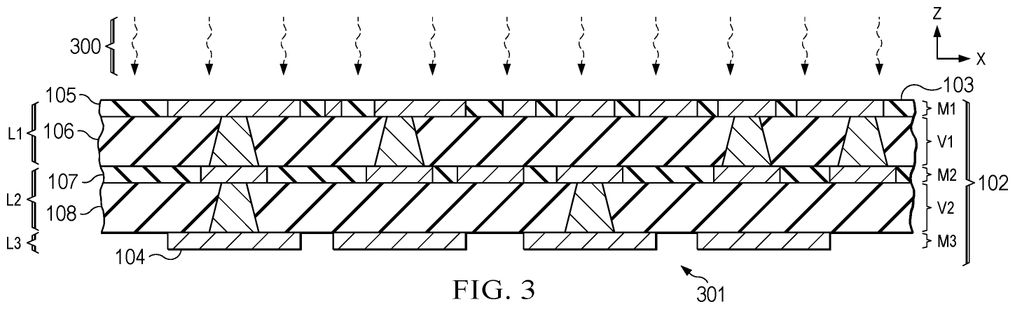

Referring also to FIGS. 2-13, FIG. 2 shows a method 200 for fabricating an electronic device, and FIG. 3-13 show the electronic device 100 of FIGS. 1 and 1A undergoing fabrication processing according to the method 200. The method 200 begins at 202 in FIG. 2 with fabrication of the soldermaskless dual side molded multilevel package substrate 102. In one implementation, the substrate 102 is fabricated in an initial or starting panel array format with rows and columns of individual unit areas corresponding to subsequently separated electronic devices to facilitate concurrent processing and reduced manufacturing cost.

In one example, the substrate fabrication at 202 includes level by level fabrication processing steps. In one implementation, for example, the individual levels are fabricated by plating a copper or other metal seed layer on a carrier structure (not shown), followed by patterned electroplating of a first trace layer and patterned conductive metal features thereof (e.g., copper features M1 in FIG. 1 above), forming a second plating mask and selectively electroplating corresponding conductive metal via features (e.g., V1), and removing the second plating mask. The individual level fabrication further includes compression molding prepreg or other suitable dielectric material (e.g., dielectric layers 105 and 106) to cover the metal trace and via features M1, B1, followed by grinding or other planarization to form the first level L1. Similar steps can be performed to form the remaining levels L2 and L3 as shown in the substrate example 102 of FIG. 1. Other suitable multilevel package substrate fabrication processes and equipment can be used in other implementations. Importantly, the substrate fabrication at 202 uses no solder mask materials and/or processing steps, thereby saving significant manufacturing time and cost. The processing at 202 does not require solder mask layer deposition or coating, exposure, development, or post development curing, thereby saving manufacturing time and cost.

At 204 in FIG. 2, one example implementation of the method 200 includes copper surface roughening to facilitate subsequent soldering operations and/or application of a finish layer over the copper or other conductive metal features of the fabricated substrate. In another implementation, the processing at 204 can be omitted.

The substrate in one example is heated at 206 in FIG. 2. FIG. 3 shows one example, in which a pre-bake process 300 is performed to bake the multilevel package substrate panel array 301, including the levels L1-L3 as described above in connection with FIGS. 1 and 1A.

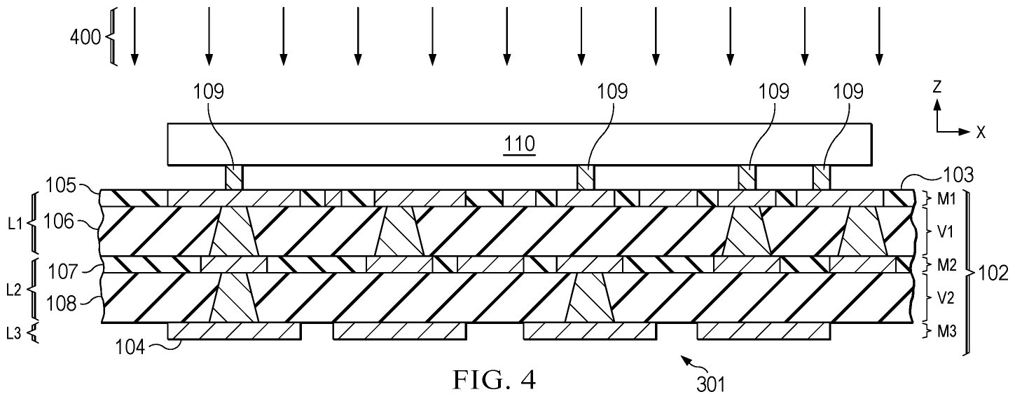

The method 200 continues in FIG. 2 with die attach processing at 208. FIG. 4 shows one example, in which a flip chip die attach process 400 is performed that attaches the semiconductor die 110 to the top or first side 103 of the soldermaskless multilevel package substrate panel array 301. One example includes automated placement of the semiconductor die 110 with the terminals 109 thereof engaging corresponding conductive metal features M1 in the first level L in each unit area of the processed soldermaskless multilevel package substrate panel array 301, for example, using automated pick and place equipment (not shown). In one implementation, the bottom sides of the individual semiconductor die terminals 109 can be provided with solder, such as by dipping prior to die placement on the panel array. In another example, a screening or printing or other process is used to form solder paste (not shown) on select portions of the top sides of one or more of the conductive metal features M1, and the placements positions the semiconductor dies 110 with the leads 109 engaging the previously applied solder paste. The flip chip die attach process 400 in one example also includes thermal processing or heating to reflow the solder to form solder joints between the bottom sides of the die terminals 109 and the corresponding conductive metal features M1 of the multilevel package substrate panel array 301. In another implementation, a semiconductor die can be attached to the first side 103 of the multilevel package substrate panel array 301 using an adhesive, along with wire bonding or other suitable electrical interconnection processing (not shown).

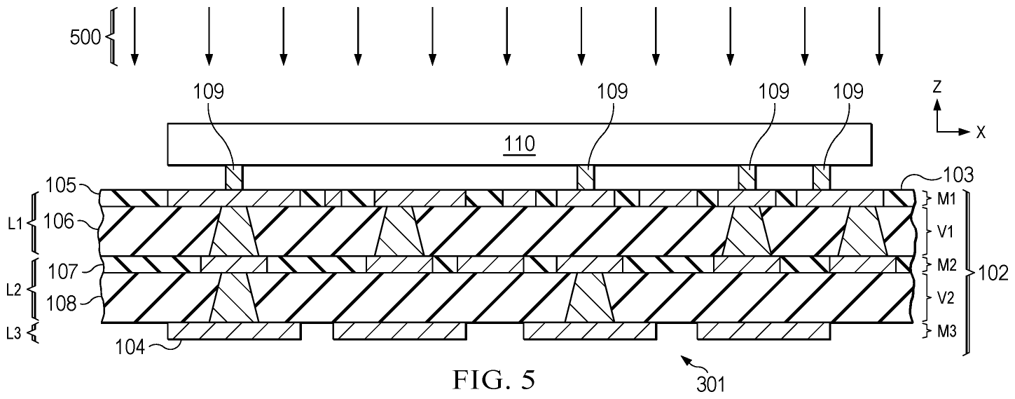

The method 200 in one example continues at 210 in FIG. 2 with flux cleaning. FIG. 5 shows one example, in which a flux cleaning process 500 is performed that removes the remnant flux from the multilevel package substrate panel array 301. In another implementation, the flux cleaning at 210 can be omitted, for example, where the die attachment processing at 208 does not involve soldering or flux.

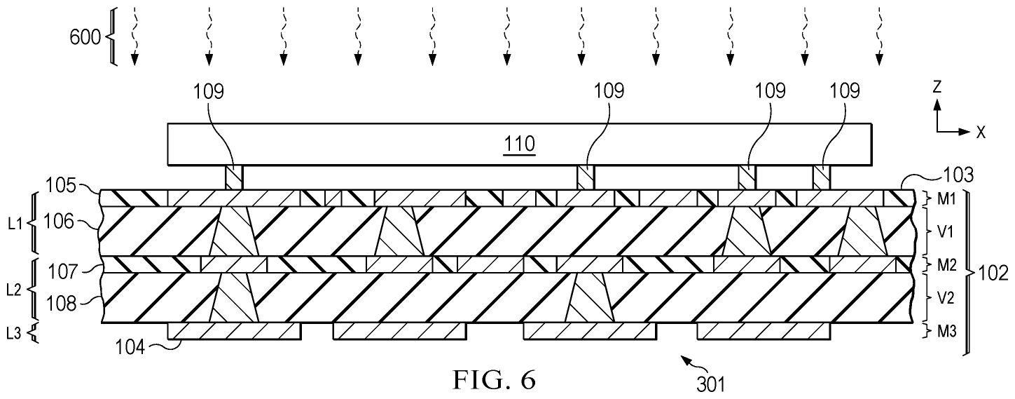

At 212 in FIG. 2, the method 200 continues with pre-mold bake processing and plasma cleaning prior to molding operations. FIG. 6 shows one example, in which processing 600 is performed that may include one or both of baking and plasma cleaning steps, for example, to facilitate subsequent molding operations to form the first and second molded package structures 111 and 112 as described above. In another implementation, one or both of the baking and/or plasma cleaning operations can be omitted.

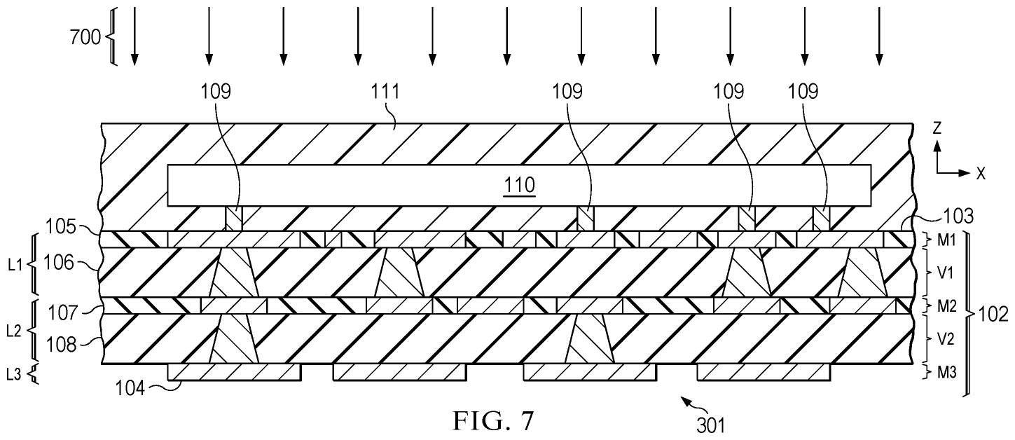

At 214 in FIG. 2, the method 200 continues with forming the first molded package structure 111 having a first thermal conductivity that is greater than 3 W/mK on the first side 103 of the multilevel package substrate panel array 301. FIG. 7 shows one example, in which a molding process 700 is performed using a mold (not shown) with a cavity or opening extending above the top side 103 of the panel array 301 and also spaced apart from and above the top side of the semiconductor die 110 in each unit area of the panel array structure 301. The molding process 700 in one example forms the first molded package structure 111 to enclose the semiconductor die 110 and to contact a portion of the first side 103 of the multilevel package substrate 102. In the illustrated example, the molded package structure 111 extends over and contacts portions of the top side 103 of the substrate 301, including areas laterally between the terminals 109 of the semiconductor die 110. In addition, the first molded package structure 111 in this example encloses the semiconductor die 110 and the terminals 109 thereof. In other examples, different mold cavities can be used, for example, to allow a portion of the semiconductor die 110 to be exposed outside the first molded package structure 111 (e.g., the top side of the semiconductor die 110). In these or another example, the mold used in the process 700 can include features which contact portions of the top side 103 of the multilevel package substrate panel array 301, and the produced first molded package structure 111 can contact or cover less than all the first or top side 103 of the first level L1 of the substrate array 301.

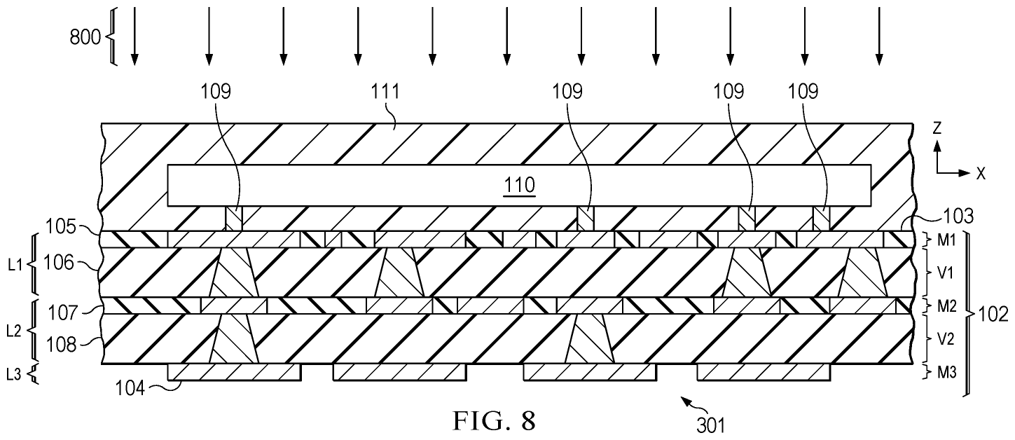

After forming the first molded package structure 111, the method 200 continues at 216 in FIG. 2 with post mold cleaning. FIG. 8 shows one example, in which a post mold cleaning process 800 is performed that cleans the molded package structure 111 and any exposed surfaces of the multilevel package substrate panel array 301. In another implementation, the Post mold cleaning at 216 can be omitted.

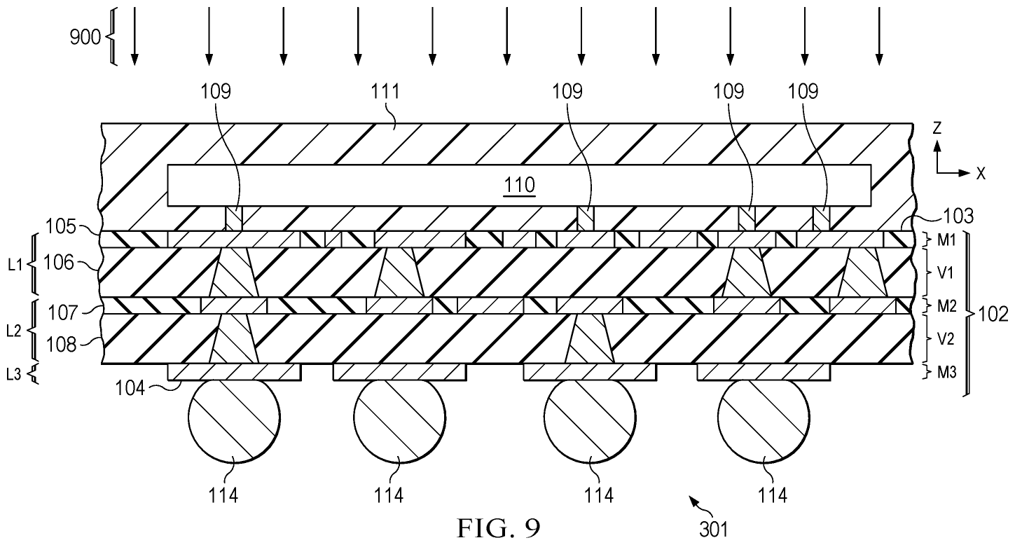

The method 200 in one example continues at 218 in FIG. 2 with solder ball attachment processing after formation of the first molded package structure 111 at 214 and any intervening post mold cleaning at 216. FIG. 9 shows one example, in which a solder ball attach process 900 is performed that attaches the solder balls 214 to corresponding conductive metal features M3 on the second or bottom side 104 of the multilevel package substrate panel array 301. Any suitable ball attach equipment and materials can be used to implement the solder ball attach process 900, for example, as is used in forming ball grid array (BGA) electronic devices. In the illustrated example, the solder ball attachment at 218 proceeds prior to forming the second molded package structure 112 of FIGS. 1 and 1A.

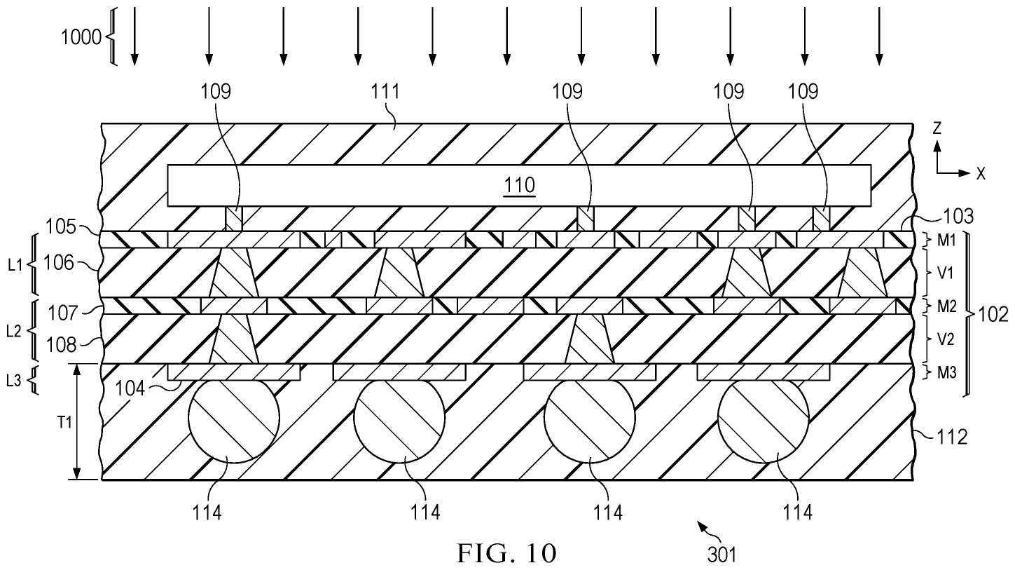

The method 200 in one example includes forming the second molded package structure 112 at 220-224 in FIG. 2. The illustrated example includes molding the bottom of the substrate at 220. FIG. 10 shows one example, in which a second molding process 1000 is performed that forms the second molded package structure 112 having a second thermal conductivity that is greater than 3 W/mK on the second side 104 of the multilevel package substrate panel array 301, where the second molded package structure 112 is spaced apart from the first molded package structure 111.

In the illustrated example, the second molding process 1000 forms the second molded package structure 112 to enclose the solder balls 114 attached to the bottom side 104 of the substrate panel array 301. In addition, the second molding process 1000 forms the second molded package structure 112 that contacts a portion of the second side 104 of the multilevel package substrate 102. In the illustrated example, the molding process 1000 completely encloses the attached solder balls 114, although not a requirement of all possible implementations.

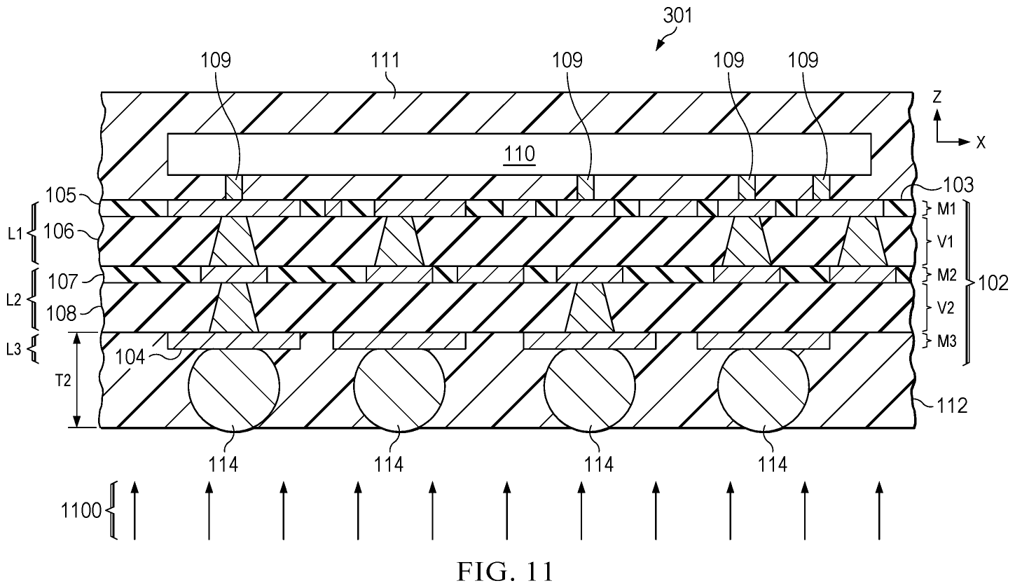

At 222 and 224 in one example, the method 200 further includes removing part of the second molded package structure 112 to expose all or a portion of the solder balls 114. The illustrated example includes grinding at 222 followed by laser ablation at 224. In other implementations a single mold material removal process can be used, or different single or multiple step material removal techniques and equipment can be used. At 222 in FIG. 2, the example method 200 includes grinding or other suitable processing to remove a first portion or part of the second molded package structure 112 to expose the solder ball 114. FIG. 11 shows one example, in which a mechanical grinding process 1100 is performed that removes a first portion of the second molded package structure 112 to expose a lower first portion of the solder balls 114.

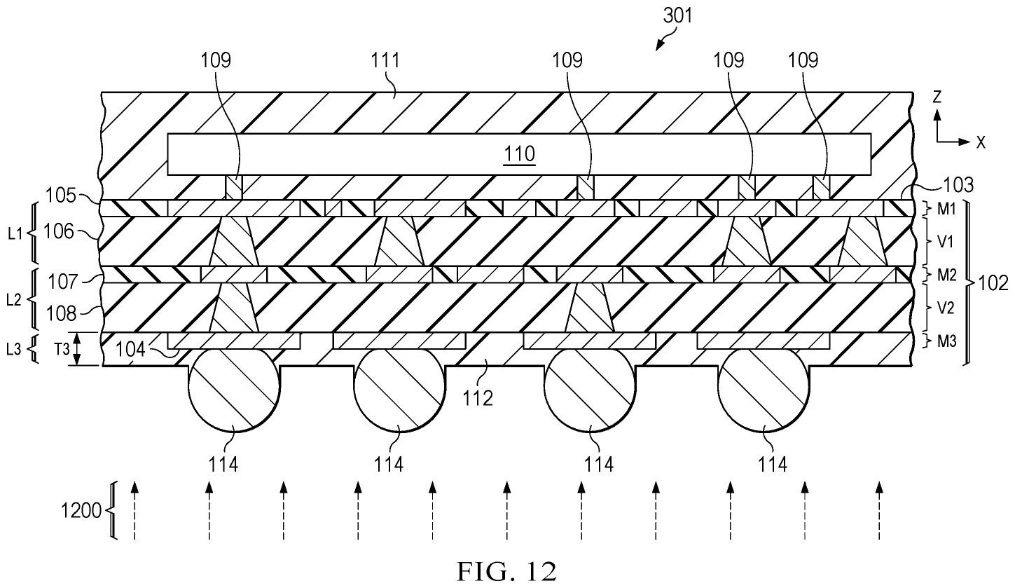

The method 200 in this example continues at 224 with laser ablation corresponding to a desired ball grid array shape based on the locations of the attached solder balls 114 along the bottom side 104 of the multilevel package substrate panel array 301. FIG. 12 shows one example, in which a laser ablation process 1200 is performed that exposes a second portion of the individual solder balls 114. In one example, the laser ablation is automated with a laser translated relative to the multilevel package substrate panel array 301 two programmatically remove the second portion of the second molded package structure 112 between the attached solder balls 114. In one implementation, the laser power and translation speed and positioning is controlled in the process 1200 in order to remove a sufficient amount of the molded package structure 112 to facilitate subsequent and user soldering of the finished electronic device to a host printed circuit board.

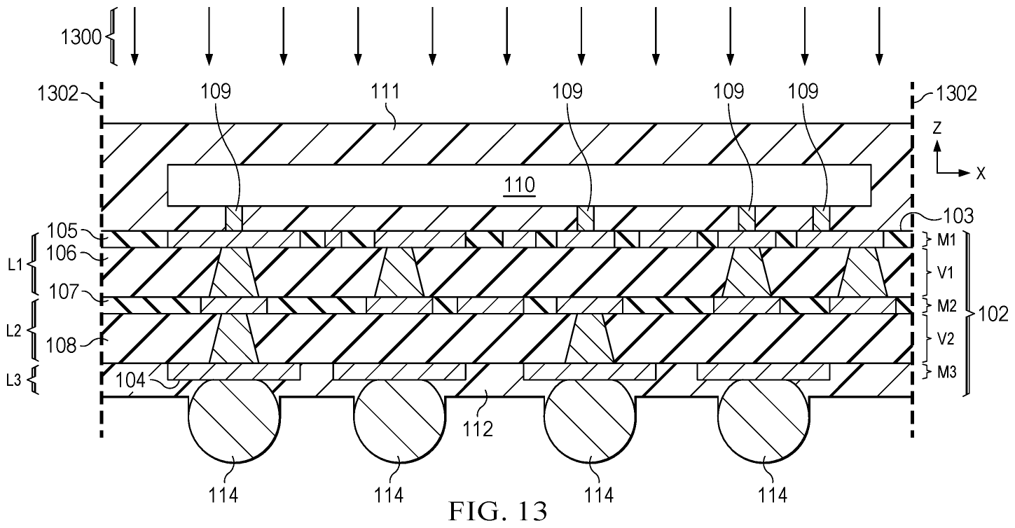

The method continues at 226 in FIG. 2 with device separation. In the illustrated example, the multilevel package substrate was fabricated and processed at 202-224 in the form of a panel array 301 having rows and columns of corresponding unit areas, each of which including a prospective packaged electronic device with a corresponding semiconductor die 110 and one or more attached solder balls 114. FIG. 13 shows one example, in which a device separation process 1300 is performed that separates the individual unit areas along lines 1302 in order to separate finished packaged electronic devices 100 from the starting panel array structure. Any suitable device separation process 1300 can be used, for example, laser cutting, saw cutting, chemical etching, or combinations thereof. In another implementation, where no panel array structure is used, the device separation processing at 226 can be omitted.

Described examples facilitate improved thermal conductivity of the soldermaskless multilevel package substrate 102 and of the finished packaged electronic device 100 beyond what is available in the industry, thereby improving package thermal dissipation in operation of the electronic device 100 and system operation when installed on a circuit board (e.g., circuit board 116 in FIG. 1 above). In addition, the described solutions advantageously reduce substrate cost by eliminating the solder mask processing from the manufacturing process used to produce the multilevel package substrate 102 in singular form or as a panel array. In addition to these benefits, the described solutions also facilitate significantly improved manufacturing yield during electronic device packaging by reducing substrate warping during thermal processing. Moreover, the processing techniques of the example fabrication method 200 can be applied using existing materials and equipment, for example, using well-developed package molding processes, grinding processes, laser ablation process is, etc.

Modifications are possible in the described examples, and other implementations are possible, within the scope of the claims.

What is claimed is:

1. An electronic device, comprising:
a multilevel package substrate having opposite first and second sides;
a semiconductor die attached to the first side;
a first molded package structure on the first side; and
a second molded package structure on the second side and spaced apart from the first molded package structure.

2. The electronic device of claim 1, wherein the first molded package structure encloses the semiconductor die.

3. The electronic device of claim 1, comprising a solder ball that contacts a conductive metal feature on the second side of the multilevel package substrate.

4. The electronic device of claim 3, wherein the second molded package structure encloses a portion of the conductive metal feature and contacts a portion of the solder ball.

5. The electronic device of claim 4, wherein the second molded package structure has a thermal conductivity that is greater than 3 W/mK.

6. The electronic device of claim 1, wherein the second molded package structure has a thermal conductivity that is greater than 3 W/mK.

7. The electronic device of claim 6, wherein the first molded package structure has a thermal conductivity that is greater than 3 W/mK.

8. The electronic device of claim 7, wherein the thermal conductivity of the second molded package structure is approximately 4.3 W/mK.

9. The electronic device of claim 7, wherein the first molded package structure has a thermal conductivity that is approximately 4.3 W/mK.

10. The electronic device of claim 1, wherein the second molded package structure has a thermal conductivity that is approximately 4.3 W/mK.

11. A system, comprising a circuit board and an electronic device attached to the circuit board, the electronic device comprising:
a multilevel package substrate having opposite first and second sides and a terminal soldered to a conductive feature of the circuit board;
a semiconductor die attached to the first side;
a first molded package structure on the first side; and
a second molded package structure on the second side and spaced apart from the first molded package structure.

12. The system of claim 11, wherein the first molded package structure encloses the semiconductor die.

13. The system of claim 11, wherein the terminal is a solder ball that contacts a conductive metal feature on the second side of the multilevel package substrate.

14. The system of claim 11, wherein the second molded package structure has a thermal conductivity that is greater than 3 W/mK.

15. The system of claim 14, wherein the thermal conductivity of the second molded package structure is approximately 4.3 W/mK.

16. A method of fabricating an electronic device, the method comprising:
attaching a semiconductor die to a first side of a soldermaskless multilevel package substrate;
forming a first molded package structure having a first thermal conductivity that is greater than 3 W/mK on the first side of the multilevel package substrate; and
forming a second molded package structure having a second thermal conductivity that is greater than 3 W/mK on an opposite second side of the multilevel package substrate and spaced apart from the first molded package structure.

17. The method of claim 16, wherein forming the first molded package structure on the first side includes performing a molding process that forms the first molded package structure to enclose the semiconductor die and to contact a portion of the first side of the multilevel package substrate.

18. The method of claim 16, further comprising, after forming the first molded package structure, and before forming the second molded package structure, attaching a solder ball to a conductive metal feature on the second side of the multilevel package substrate.

19. The method of claim 18, wherein forming the second molded package structure comprises:
performing a molding process that forms the second molded package structure to enclose the solder ball and to contact a portion of the second side of the multilevel package substrate; and
removing part of the second molded package structure to expose the solder ball.

20. The method of claim 19, wherein removing part of the second molded package structure comprises:
performing a grinding process that removes a first portion of the second molded package structure to expose a first portion of the solder ball; and
performing a laser ablation process to expose a second portion of the solder ball.

21. A method of reducing substrate warpage, comprising:
forming a soldermaskless multilevel package substrate with no solder mask;
forming a first molded package structure having a first thermal conductivity that is greater than 3 W/mK on the first side of the soldermaskless multilevel package substrate; and
forming a second molded package structure having a second thermal conductivity that is greater than 3 W/mK on an opposite second side of the soldermaskless multilevel package substrate and spaced apart from the first molded package structure.
